(19) United States
(12) Patent Application Publication
(10) Pub. No.: US 2015/0155194 A1
(43) Pub. Date: Jun. 4, 2015

(54) METHOD OF PREPARING HETEROGENEOUS STACKED CO-FIRED CERAMIC FOR USE IN AN ALUMINUM NITRIDE ELECTROSTATIC CHUCK

(71) Applicant: NATIONAL CHUNG SHAN INSTITUTE OF SCIENCE AND TECHNOLOGY, Longtan Township (TW)

(72) Inventors: YANG-KUO KUO, LONGTAN TOWNSHIP (TW); JIAN-LONG RUAN, LONGTAN TOWNSHIP (TW); CHENG-HUNG SHIH, LONGTAN TOWNSHIP (TW); LEA-HWUNG LEU, LONGTAN TOWNSHIP (TW)

(73) Assignee: NATIONAL CHUNG SHAN INSTITUTE OF SCIENCE AND TECHNOLOGY, Longtan Township (TW)

(21) Appl. No.: 14/280,703

(22) Filed: May 19, 2014

(30) Foreign Application Priority Data
Nov. 29, 2013 (TW) 102143661

(51) Int. Cl. H01L 21/683; C04B 37/00

(52) U.S. Cl. CPC H01L 21/6833; C04B 37/00

(57) ABSTRACT

A method of preparing a heterogeneous stacked co-fired ceramic for use in an aluminum nitride-based electrostatic chuck includes providing a first aluminum nitride blank layer; applying a metal ink to the first aluminum nitride blank layer to form thereon an electrostatic electrode layer by screen printing, wherein the metal ink mainly contains a metal of high melting point; stacking a second aluminum nitride blank layer on the electrostatic electrode layer; laminating the first aluminum nitride blank layer, the electrostatic electrode layer, and the second aluminum nitride blank layer (collectively known as a heterogeneous ceramic) together; and co-firing the laminated heterogeneous ceramic in accordance with a sintering temperature rising curve to prepare the heterogeneous stacked co-fired ceramic characterized by reduced differences in sintering shrinkage ratio between the electrostatic electrode and aluminum nitride blank and enhanced strength and adhesion of the interface between the electrostatic electrode and aluminum nitride blank.

### CROSS-REFERENCE TO RELATED APPLICATION

This non-provisional application claims priority under 35 U.S.C. §119(a) on Patent Application No(s). 102143661 filed in Taiwan, R.O.C. on Nov. 29, 2013, the entire contents of which are hereby incorporated by reference.

### FIELD OF TECHNOLOGY

The present invention relates to methods of preparing heterogeneous stacked co-fired ceramics, and more particularly, to a method of co-firing a heterogeneous ceramic for use in an aluminum nitride electrostatic chuck and, in particular, a method of co-firing a metal and a ceramic, with a view to reducing the difference in sintering shrinkage ratio between an electrostatic electrode and an aluminum nitride blank and enhancing the strength and adhesion of the interface between the electrostatic electrode and the aluminum nitride blank.

### BACKGROUND

During the present semiconductor wafer fabrication, a silicon wafer is no longer held with mechanical clamps; instead, an electrostatic chuck (ESC) electrostatically clamps onto the silicon wafer. In addition to its clamping function, the electrostatic chuck not only overcomes the drawbacks of the mechanical clamps, namely warpage, edge exclusion, microparticle contamination, and short service life, but also augments the contact between the wafer and the chuck, enhances the heat transfer there between, and enables efficient cooling, not to mention that the chuck is not placed in direct exposure to plasma, thereby enhancing the process efficiency, yield, and quality greatly. Therefore, electrostatic chucks are indispensable to semiconductor wafer fabrication nowadays.

In general, a conventional electrostatic chuck comprises multiple dielectric layers on an electrode in control of adhesion, response time of chucking and de-chucking, operating voltage, heat transfer, chemical and mechanical strength, and durability. Another conventional electrostatic chuck is characterized by a metallic electrode embedded in the dielectric. The dielectric for use in conventional electrostatic chucks includes ceramic (which demonstrates excellent mechanical properties and high efficiency of heat transfer), polyimide, or any appropriate polymers, such that the electrostatic chucks not only chuck and de-chuck wafers in a short response time, but also dissipate heat from the wafers quickly. Furthermore, none of the mechanical components of the electrostatic chucks are exposed to plasma, and thus wear and tear of the mechanical components of the electrostatic chucks is unlikely to happen, thereby prolonging the expected service life of the electrostatic chucks. There are two purposes of the dielectric layers of the electrostatic chuck, namely generating an electrostatic force, and preventing direct electrical contact between an electrode and a wafer, because any direct electrical contact between an electrode and a wafer interferes with radio frequency (RF) currents applied to the wafers and eventually compromises the wafer fabrication process. A comparison of physical properties of dielectric materials for making dielectric layers of an electrostatic chuck is shown Table 1 below.

TABLE 1
a comparison of physical properties of dielectric materials
for making dielectric layers of an electrostatic chuck

| | Al₂O₃ | SiO₂ | Si₃N₄ | AlN |
|---|---|---|---|---|
| Dielectric constant | 9.8~10.8 | 3.8~4.8 | 4.5~7.0 | 8.5~9.1 |
| Thermal conductivity | 17~27 | 1.2~1.5 | 80~150 | 170~230 |
| (W/mK) | | | | |

Electrodes for use in conventional electrostatic chucks are made of aluminum. The hardness and flatness of the surfaces of the electrodes is increased by allowing the electrodes to undergo surface anodizing treatment which entails forming an aluminum oxide dielectric layer of a thickness of 50 μm on the aluminum-made electrodes. However, due to advancement of semiconductor manufacturing processes, for example, an ever-increasing plasma power and density, the aluminum oxide dielectric layer of the electrodes for use in conventional electrostatic chucks is becoming less resistant to plasma bombardment at high power and density, thereby manifesting deteriorating durability. Furthermore, aluminum oxide has a low coefficient of thermal conductivity and thus is not only ineffective in dissipating the high heat generated as a. result of plasma bombardment at high power and density but also inapplicable to temperature-dependent manufacturing processes at extreme temperatures. Hence, it is of vital importance that ceramics, which are highly effective dissipating heat, are used in making the dielectric layers of electrostatic chucks. The thermal conductivity (170-230 W/mK) of aluminum nitride is 8-10 times higher than that of aluminum oxide. Furthermore, aluminum nitride has a low coefficient of thermal expansion (4.5×10⁻⁶/° C. and thus is compatible with silicon and the other semiconductors. Aluminum nitride manifests high electrical insulation capability, has a low dielectric constant, and demonstrates higher mechanical strength than aluminum oxide. Aluminum nitride is good at anti-corrosion and durability, and thus aluminum nitride is suitable for use in making the dielectric layers of electrostatic chucks operable in high-power high-density plasma and at a high temperature, so that the durability of the electrostatic chucks remains unaffected by adverse environment.

There are various sintering-related processes for use in manufacturing ceramic-made cooling substrates, including a low-temperature co-fired ceramic (LTCC) process and a high-temperature co-fired ceramic (HTCC) process. The LTCC process involves mixing ceramic powder, glass, and an organic binding agent to form a paste, taping the paste to form a blank, and forming vias in the blank to enable signals to be transmitted across the blank. As regards the internal circuits of the LTCC process, bores in the blank are filled by screen printing, and circuits are formed on the blank by screen printing, so as to form internal and external electrodes, stack the blanks, and sinter the blanks at 850° C.˜900° C. The high-temperature co-fired ceramic (HTCC) process dispenses with the glass, but requires forming vias in a dry blank, filling the bores in the blank by screen printing, forming circuits on the blank by screen printing, stacking the blanks, and sintering the blanks at 1300° C.˜1600° C. The HTCC process has a disadvantage, that is, limited choices of metal electrode materials, because the aforesaid sintering step must take place at a high temperature.

Both the LTCC and HTCC processes must entail stacking the blanks before sintering the blanks, and, as a result, the shrinkage ratio poses a problem. According to the prior art, aluminum nitride ceramic is embedded in the electrostatic electrode to undergo one-time sintering. After the sintering step has been finished, not only is the strength and adhesion of the resultant interface between the electrostatic electrode layer and the aluminum nitride layer unsatisfactory, but the electrostatic electrode layer differs from the aluminum nitride layer in terms of the sintering shrinkage ratio, not to mention that both the electrostatic electrode layer and the aluminum nitride layer are flawed macroscopically or microscopically, thereby deteriorating the heterogeneous bonding between the electrostatic electrode and the aluminum nitride, reducing precision of metallic wiring, and comprising the yield and electrical properties of the electrostatic chuck.

According to the prior art, a heater material is applied to the back of the suction surface of the electrostatic chuck by screen printing and then the heating material is heated up to cure the heating material, so that a metallic film or a sheet-shaped conductive material are adhered to the inside of the electrostatic chuck having an additional heater function. As soon as the organic binding agent adheres the electrostatic chuck to a temperature adjustment-oriented base, not only are pores formed in the organic binding agent, but also are dented non-adhering portions formed between the organic binding agent and the electrostatic chuck as well as between the organic binding agent and the temperature adjustment-oriented base; as a result, as soon as a voltage is applied to the heater material, a short circuit is developed between the electrostatic chuck and the temperature adjustment-oriented base, thereby increasing the likelihood of insulation failure.

### SUMMARY

In view of the aforesaid drawbacks of the prior art, it is an objective of the present invention to provide a method of preparing co-fired structure of stacked aluminum nitride layer/electrostatic electrode layer/aluminum nitride layer, which is for use in an aluminum nitride electrostatic chuck, with a view to reducing a difference in sintering shrinkage ratio between the electrostatic electrode and aluminum nitride blank, enhancing the reliability of the embedded electrostatic electrode, and enhancing the stability of the laminated aluminum nitride-based co-fired ceramic in terms of dimensions and structure. The present invention is advantageous as compared to the prior art in that: an embedded metallic wiring is not formed by sintering an embedded metal layer once, but is formed by co-firing stacked multiple layers of ceramics and metallic wirings, so as to apply a high-accuracy metallic wiring by a high-precision screen printing technique before the sintering process is carried out, allow the multiple stacked ceramic layers co-firing process to take place at a low temperature, and overcome a drawback of the prior art, that is, a metal layer embedded ceramic formed by sintering an embedded metal layer once at a high temperature is flawed with unsatisfactory precision, low yield, and deteriorated electrical properties of the embedded metallic wiring thus manufactured.

In general, screen printing entails forming a thick-film pattern on an appropriate substrate and enabling anticipated properties of the thick film, such as mechanical properties, electrical properties, and optical properties, to be manifested by means of a proper thermal reaction. In addition to the thick film, screen printing requires a metal printing-oriented conductive paste for use in its two important steps, namely the thick-film pattern forming step, and the thermal reaction step, wherein the conductive paste is applied to any internal electrode mounted on the substrate in order to manufacture a high-capacity laminated ceramic component. Poor printing quality comprises electrical conduction (impedance) properties, voltage tolerance, and reliability of the thick-film components.

The primary objective of the present invention is to provide a method of preparing a heterogeneous stacked co-fired ceramic for use in an aluminum nitride-based electrostatic chuck. The method comprises the steps of: providing a first aluminum nitride blank layer, wherein the first aluminum nitride blank layer is previously formed by tape casting and then blanking and is of a thickness of 0.4 mm to 0.8 mm; applying a metal ink to the first aluminum nitride blank layer to form thereon an electrostatic electrode layer by screen printing, wherein the metal ink mainly contains a metal of high melting point; stacking a second aluminum nitride blank layer on the electrostatic electrode layer; laminating the first aluminum nitride blank layer, the electrostatic electrode layer, and the second aluminum nitride blank layer (collectively known as a. heterogeneous ceramic) together; and co-firing the laminated heterogeneous ceramic in accordance with a. sintering temperature rising curve to prepare the heterogeneous stacked co-fired ceramic. During the process flow of the method, both the thickness of the aluminum nitride blanks and the types of the materials for making the electrostatic electrode are adjustable; this, coupled with the specially designed sintering temperature rising curve, renders it efficient to prepare a heterogeneous stacked co-fired ceramic for use in an aluminum nitride-based electrostatic chuck, with a view to reducing the differences in sintering shrinkage ratio between an electrostatic electrode and an aluminum nitride ceramic and enhancing the strength and adhesion of the interface between the electrostatic electrode and the aluminum nitride blank.

The metal ink for use in forming the electrostatic electrode layer and the heating electrode layer by screen printing comprises tungsten or molybdenum, whereas lamination is performed on the heterogeneous ceramic at a specific temperature of 70-130° C. and a specific pressure of 30-50 MPa. The laminated heterogeneous ceramic is co-fired at temperature increasing from a room temperature to a co-firing temperature according to a sintering temperature rising curve so as to prepare the heterogeneous stacked co-fired ceramic. The sintering temperature rising curve depicts raising temperature in two stages, the first stage involves raising temperature at a temperature rising speed of 2˜5° C./min from the room temperature to 1000˜1300° C. and then keeping the temperature of 1000˜1300° C. for 1˜2 hours, and the second stage involves raising temperature at a temperature rising speed of 1˜3° C./min from 1000˜1300° C. to 1600˜1900° C. and then keeping the temperature of 1600˜1900° C. for 8×15 hours. Afterward, the sintering temperature rising curve depicts lowering temperature in two stages, the first stage involves lowering temperature at a temperature dropping speed of 1˜3° C./min from 1600˜1900° C. to 1000˜1300° C. and then keeping the temperature of 1000˜1300° C. for 1×2 hours, and the second stage involves lowering temperature at a temperature dropping speed of 1˜3° C./min from 1000˜1300° C. to the room temperature.

The aforesaid technique of sintering the electrostatic electrode wiring layer and the aluminum nitride ceramic blanks concurrently according to the present invention has advantages over the prior art which discloses performing ceramic sintering and then combining the sintered ceramic with an electrostatic electrode, namely reducing processing steps, enhancing the stability and reliability of the sintered finished products effectively, reducing the difference in sintering shrinkage ratio between an electrostatic electrode and an aluminum nitride blank, and enhancing the strength and adhesion of the interface between the electrostatic electrode and the aluminum nitride blank.

The above overview and the ensuing description are intended to explain the way, means, and advantages of achieving the anticipated objectives of the present invention. The other objectives and advantages of the present invention are also explained in the description below.

### BRIEF DESCRIPTION

Objectives, features, and advantages of the present invention are hereunder illustrated with specific embodiments in conjunction with the accompanying drawings, in which:

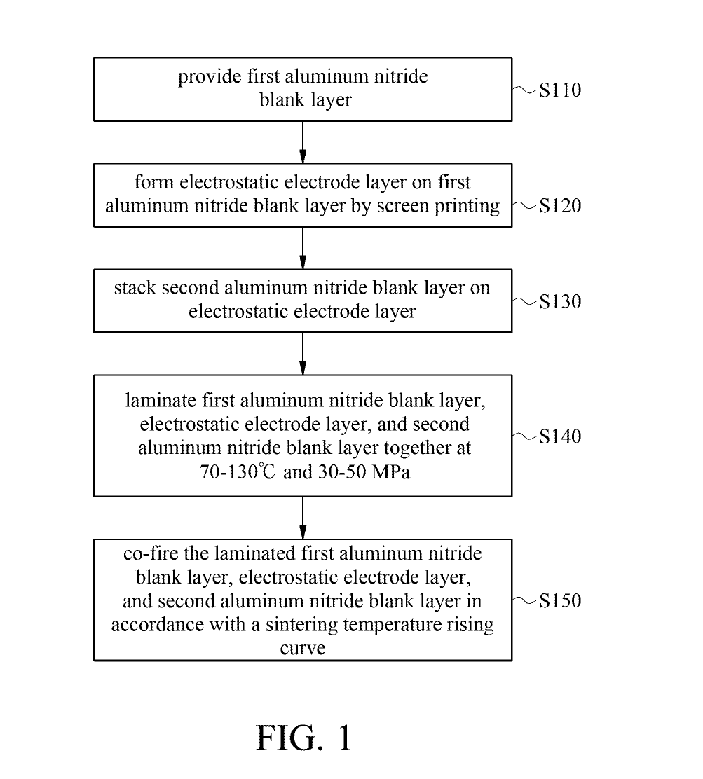

FIG. 1 is a schematic view of the process flow of a method of preparing a heterogeneous stacked co-fired ceramic according to the present invention;

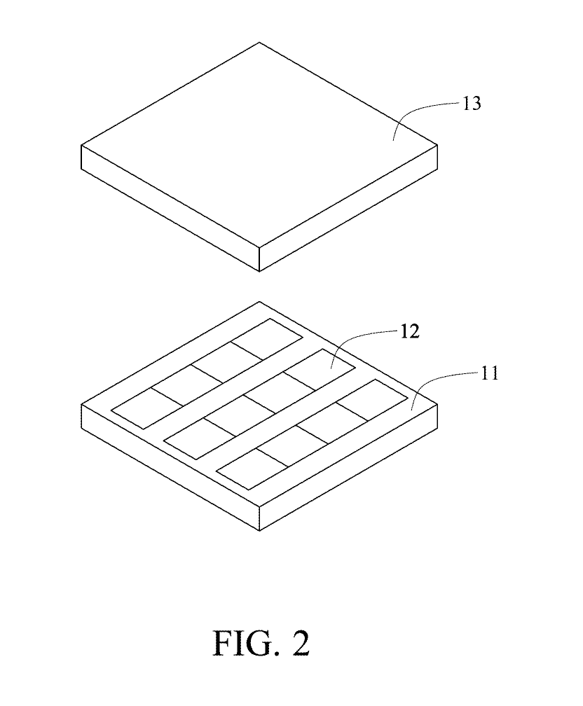

FIG. 2 is a schematic view of the structure of the heterogeneous stacked co-fired ceramic according to the present invention;

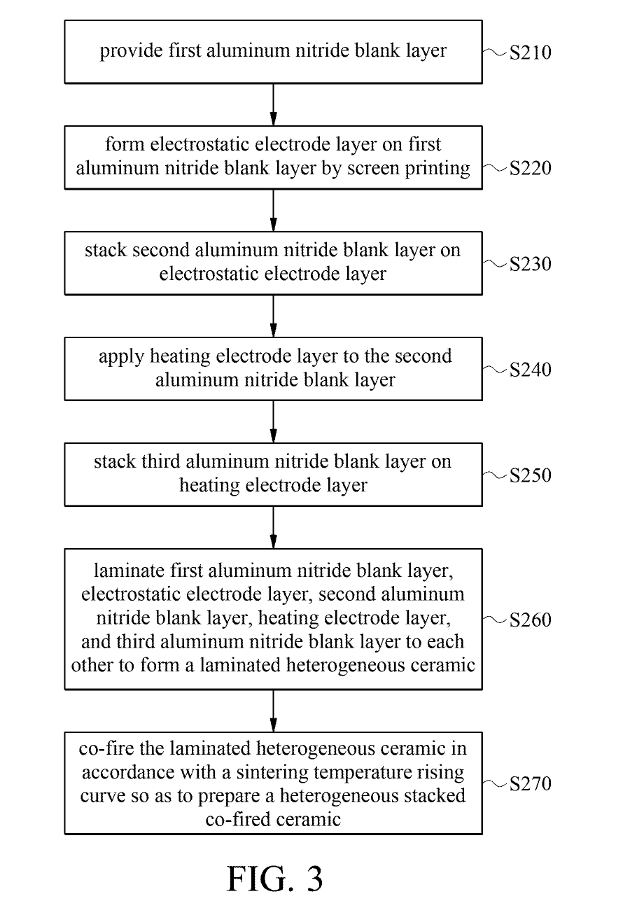

FIG. 3 is a schematic view of the process flow of the method of preparing a five-layer heterogeneous stacked co-fired ceramic according to the present invention; and

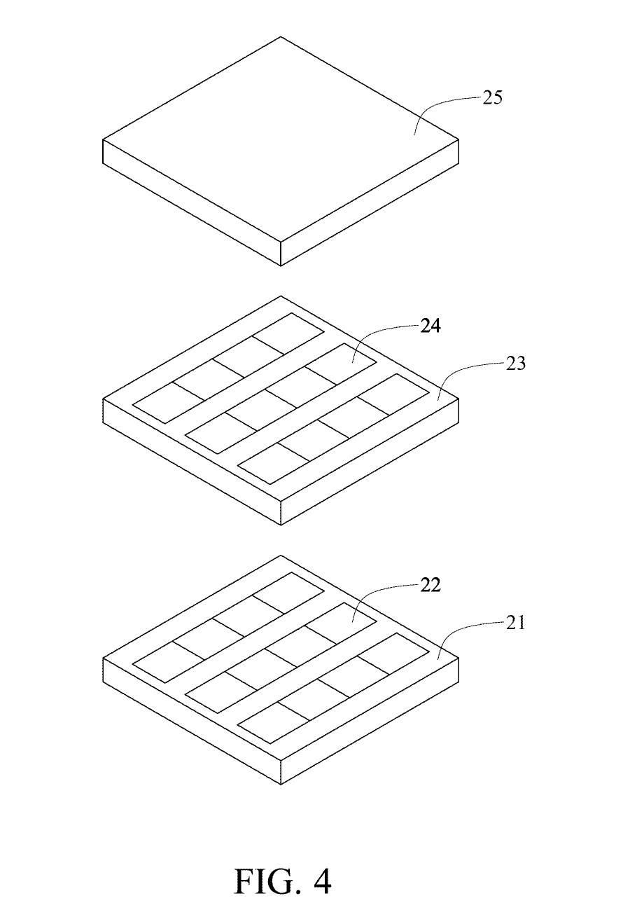

FIG. 4 is a schematic view of the structure of the five-layer heterogeneous stacked co-fired ceramic according to the present invention.

### DETAILED DESCRIPTION

### Embodiment 1

Referring to FIG. 1 and FIG. 2, there are shown a schematic view of the process flow of a method of preparing a heterogeneous stacked co-fired ceramic according to the present invention, and a schematic view of the structure of the heterogeneous stacked co-fired ceramic according to the present invention, respectively. In embodiment 1 of the present invention, the method of preparing the heterogeneous stacked co-fired ceramic comprises the steps of: providing a first aluminum nitride blank layer 11 (S110), wherein the first aluminum nitride blank layer 11 is previously formed by tape casting and then blanking; forming an electrostatic electrode layer 12 on the first aluminum nitride blank layer 11 by screen printing (S120); stacking a second aluminum nitride blank layer 13 on the electrostatic electrode layer 12 (S130); performing lamination on the first aluminum nitride blank layer, the electrostatic electrode layer, and the second aluminum nitride blank layer (collectively known as a heterogeneous ceramic) at a specific temperature and pressure (S140); and co-firing the laminated heterogeneous ceramic at temperature increasing from a room temperature to a co-firing temperature according to a sintering temperature rising curve so as to prepare the heterogeneous stacked co-fired ceramic (S150).

### Embodiment 2

Referring to FIG. 3 and FIG. 4, there are shown a. schematic view of the process flow of the method of preparing a five-layer heterogeneous stacked co-fired ceramic according to the present invention, and a schematic view of the structure of the five-layer heterogeneous stacked co-fired ceramic according to the present invention, respectively. In embodiment 2 of the present invention, the method of preparing the five-layer heterogeneous stacked co-fired ceramic comprises the steps of: providing a first aluminum nitride blank layer 21 (S210), wherein the first aluminum nitride blank layer 21 is previously formed by tape casting and then blanking; forming an electrostatic electrode layer 22 on the first aluminum nitride blank layer 21 by screen printing (S220); stacking a second aluminum nitride blank layer 23 on the electrostatic electrode layer 22 (S230); forming a heating electrode layer 24 on the second aluminum nitride blank layer 23 by screen printing (S240); stacking a third aluminum nitride blank layer 25 on the heating electrode layer 24 (S250); laminating the first aluminum nitride blank layer, the electrostatic electrode layer, the second aluminum nitride blank layer, the heating electrode layer, and the third aluminum nitride blank layer (collectively known as a heterogeneous ceramic) to each other at a. specific temperature and pressure (S260); and co-firing the laminated heterogeneous ceramic at temperature increasing from a room temperature to a co-firing temperature according to a sintering temperature rising curve so as to prepare the heterogeneous stacked co-fired ceramic (S270).

In the above embodiments of the present invention, the metal ink for use in forming the electrostatic electrode layer and the heating electrode layer by screen printing comprises tungsten or molybdenum, whereas lamination is performed on the heterogeneous ceramic at a specific temperature of 70-130° C. and a specific pressure of 30-50 MPa. The laminated heterogeneous ceramic is co-fired at temperature increasing from a room temperature to a co-firing temperature according to a sintering temperature rising curve so as to prepare the heterogeneous stacked co-fired ceramic. The sintering temperature rising curve depicts raising temperature in two stages, the first stage involves raising temperature at a temperature rising speed of 2˜5° C./min from the room temperature to 1000˜1300° C. and then keeping the temperature of 1000˜1300° C. for 1˜2 hours, and the second stage involves raising temperature at a temperature rising speed of 1˜3° C./min from 1000˜1300° C. to 1600˜1900° C. and then keeping the temperature of 1600˜1900° C. for 8×15 hours. Afterward, the sintering temperature rising curve depicts lowering temperature in two stages, the first stage involves lowering temperature at a temperature dropping speed of 1˜3° C./min from 1600˜1900° C. to 1000˜1300° C. and then keeping the temperature of 1000˜1300° C. for 1—2 hours, and the second stage involves lowering temperature at a temperature dropping speed of 1˜3° C./min from 1000˜1300° C. to the room temperature.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A method of preparing a heterogeneous stacked co-fired ceramic for use in an aluminum nitride-based electrostatic chuck, the method comprising the steps of:
(A) providing a first aluminum nitride blank layer;
(B) applying a metal ink to the first aluminum nitride blank layer to form thereon an electrostatic electrode layer by screen printing;
(C) stacking a second aluminum nitride blank layer on the electrostatic electrode layer, wherein the first aluminum nitride blank layer, the electrostatic electrode layer, and the second aluminum nitride blank layer thus stacked up are collectively known as a heterogeneous ceramic;
(D) performing lamination on the heterogeneous ceramic at a temperature of 70-130° C. and a pressure of 30-50 MPa; and
(E) co-firing the laminated heterogeneous ceramic at temperature increasing from a room temperature to a co-firing temperature according to a sintering temperature rising curve so as to prepare the heterogeneous stacked co-fired ceramic.

2. The method of claim 1, wherein the metal ink of step (B) comprises one of tungsten and molybdenum.

3. The method of claim 1, wherein the first aluminum nitride blank layer of step (A) and the second aluminum nitride blank layer of step (C) are each formed by tape casting and blanking and are each of a thickness of 0.4 mm to 0.8 mm.

4. The method of claim 1, wherein in step (D) the temperature is preferably 80° C. and the pressure is preferably 30 MPa.

5. The method of claim 1, wherein in step (E) the sintering temperature rising curve depicts raising temperature from the room temperature to the co-firing temperature of 1600˜1900° C. in two stages and then lowering temperature from the co-firing temperature of 1600˜1900° C. to the room temperature in two stages.

6. The method of claim 5, wherein the sintering temperature rising curve depicts raising temperature in two stages, the first stage involves raising temperature at a temperature rising speed of 2˜5° C./min from the room temperature to 1000˜1300° C. and then keeping the temperature of 1000˜1300° C. for 1˜2 hours, and the second stage involves raising temperature at a temperature rising speed of 1˜3° C./min from 1000˜1300° C. to 1600˜1900° C. and then keeping the temperature of 1600˜1900° C. for 8˜15 hours.

7. The method of claim 5, wherein the sintering temperature rising curve depicts lowering temperature in two stages, the first stage involves lowering temperature at a temperature dropping speed of 1˜3° C./min from 1600˜1900° C. to 1000˜1300° C. and then keeping the temperature of 1000˜1300° C. for 1˜2 hours, and the second stage involves lowering temperature at a temperature dropping speed of 1˜3° C./min from 1000˜1300° C. to the room temperature.

8. The method of claim 1, wherein step (C) is followed by the step of applying a metal ink to the second aluminum nitride blank layer to form thereon a heating electrode layer and then the step of stacking a third aluminum nitride blank layer on the heating electrode layer.

9. The method of claim 8, wherein the metal ink comprises one of tungsten and molybdenum.

10. The method of claim 8, wherein the heating electrode layer is formed on the second aluminum nitride blank layer by screen printing.

11. The method of claim 8, wherein in step (E) the sintering temperature rising curve depicts raising temperature in two stages, the first stage involves raising temperature at a temperature rising speed of 2˜5° C./min from the room temperature to 1000˜1300° C. and then keeping the temperature of 1000˜1300° C. for 1˜2 hours, and the second stage involves raising temperature at a temperature rising speed of 1˜3° C./min from 1000˜1300° C. to 1600˜1900° C. and then keeping the temperature of 1600˜1900° C. for 8˜15 hours, and depicts lowering temperature in two stages, the first stage involves lowering temperature at a temperature dropping speed of 1˜3° C./min from 1600˜1900° C. to 1000˜1300° C. and then keeping the temperature of 1000˜1300° C. for 1˜2 hours, and the second stage involves lowering temperature at a temperature dropping speed of 1˜3° C./min from 1000˜1300° C. to the room temperature.
